(19) United States
(12) Patent Application Publication
(10) Pub. No.: US 2009/0056989 A1
(43) Pub. Date: Mar. 5, 2009

(54) PRINTED CIRCUIT BOARD AND METHOD FOR PREPARATION THEREOF

(75) Inventors: Omar Bchir, Phoenix, AZ (US); Islam Salama, Chandler, AZ (US); Charan Gurumurthy, Higley, AZ (US)

Correspondence Address: GROSSMAN, TUCKER, PERREAULT & PFLEGER, PLLC;C/O Intellevate, LLC, P. O. BOX 52050, MINNEAPOLIS, MN, 55402, US

(73) Assignee: INTEL CORPORATION, Santa Clara, CA (US)

(21) Appl. No.: 11/845,404

(22) Filed: Aug. 27, 2007

(51) Int. Cl. H05K 1/09; H05K 1/00; H05K 3/02

(52) U.S. Cl. 174/256; 174/250; 29/846

(57) ABSTRACT

Disclosed is a method for preparing a printed circuit board. The method comprises forming a conductive layer on an insulated layer substrate. The method further includes partitioning the conductive layer into a first area and a second area by applying a photoresist mask. Furthermore, the method includes applying a first etching process to the conductive layer to pattern a first set of features on the first area of the conductive layer. Thereafter, the method includes applying a second etching process to the conductive layer to pattern a second set of features on the second area of the conductive layer. The second set of features on the second area of the conductive layer has a finer pitch as compared to the first set of features on the first area of the conductive layer.

### FIELD

The present disclosure generally relates to printed circuit boards and, more particularly, to a method for preparing a printed circuit board.

### BRIEF DESCRIPTION OF THE DRAWINGS

The advantages and features of the present disclosure will become better understood with reference to the following detailed description and claims taken in conjunction with the accompanying drawings, wherein like elements are identified with like symbols, and in which:

FIG. 1 is a schematic diagram of a prior-art printed circuit board; and

FIGS. 2A and 2B are schematic diagrams illustrating a printed circuit board, according to an exemplary embodiment of the present disclosure.

Like reference numerals refer to like parts throughout the description of several views of the drawings.

### DETAILED DESCRIPTION OF THE DISCLOSURE

For a thorough understanding of the present disclosure, reference is to be made to the following detailed description, including the appended claims, in connection with the above-described drawings. Although the present disclosure is described in connection with exemplary embodiments, the present disclosure is not intended to be limited to the specific forms set forth herein. It is understood that various omissions and substitutions of equivalents are contemplated as circumstances may suggest or render expedient, but these are intended to cover the application or implementation without departing from the spirit or scope of the claims of the present disclosure. Also, it is to be understood that the phraseology and terminology used herein is for the purpose of description and should not be regarded as limiting.

The terms “first,” “second,” and the like, herein do not denote any order, quantity, or importance, but rather are used to distinguish one element from another. The terms “a” and “an” herein do not denote a limitation of quantity, but rather denote the presence of at least one of the referenced item.

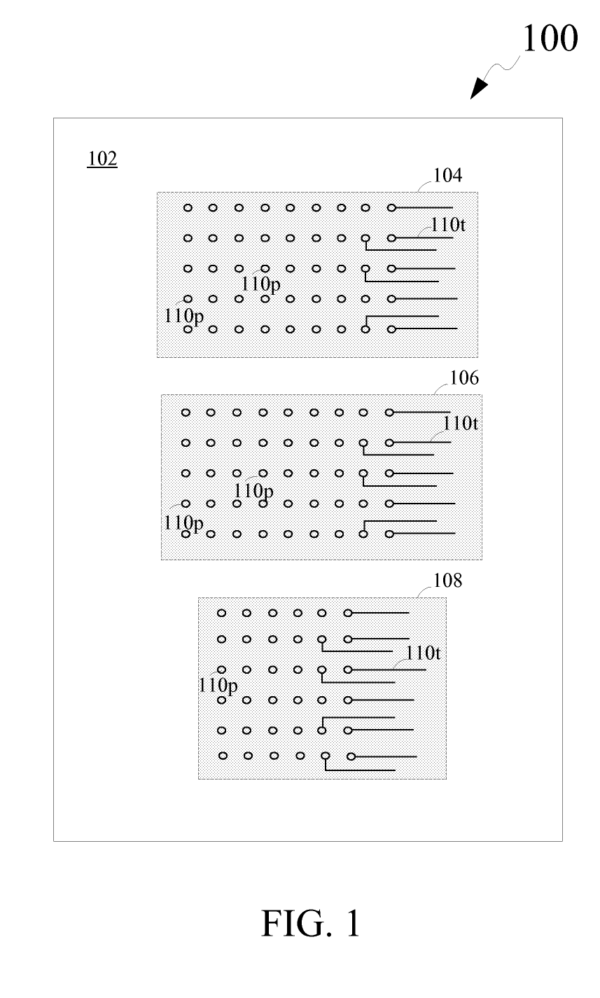

Referring to FIG. 1, a schematic diagram of a prior-art printed circuit board (PCB) 100, is shown. The schematic diagram of FIG. 1 is an exemplary representation of a top-view of a conventional printed circuit board 100 (hereinafter referred to as ‘PCB 100’). As shown in FIG. 1, the PCB 100 comprises a conductive layer 102 having a feature 104, a feature 106 and a feature 108. The features 104, 106 and 108 include pads 110p and traces 110t. Generally, the conductive layer 102 is made of copper (Cu), which is formed on an insulated layer (not shown). The PCB 100 uses subtractive etching of the conductive layer 102 to pattern the features 104, 106 and 108. A typical PCB 100 is intended to accommodate various electronic components. Such electronic components may include, but are not limited to, logic circuits, analog circuits, Central Processing Units (CPU) and chipsets. These electronic components and various subsystems of these electronic components may be mounted on the PCB 100 through the pads 110p and are connected through the traces 110t. The feature 104 may correspond to a chipset region, the feature 106 may correspond to a CPU region, and the feature 108 may correspond to other electronic components region.

The use of the subtractive etching on the entire PCB 100 may limit pitch of the PCB 100. As used herein, a ‘pitch’ refers to a minimum dimension of the pads 110p, the traces 110t, spacing between the pads 110p, and spacing between the traces 110t in the features 104, 106 and 108. With the use of the subtractive etching of the Cu layer, maintaining a pitch of less than 0.5 mm of the PCB 100 may be difficult. In a typical PCB 100, the specifications for line-width to space-width ratio (L/S) is about 75/75 (μm/μm) for a 9 μm thick Cu layer. Features 104, 106 and 108 may be patterned irrespective of the electronic components that are to be added. For example, as shown in FIG. 1, the line widths of the traces 110t, the space widths between the traces 110t and spacing between the pads 110p are same in the features 104, 106 and 108. However, a finer pitch is desired for the chipset region and the CPU region than other regions in a PCB. The present disclosure provides a method of preparing a PCB with reduced pitch and L/S specifications in a simple, reliable, and cost-effective manner.

The present disclosure provides a PCB with reduced pitch and L/S specifications in a CPU region and a chipset region of the PCB to promote form factor reduction (i.e., to promote substrate cost savings). This may be achieved by leaving a conductive layer of the PCB un-patterned in the pad/routing area for a CPU and/or the chipset of the PCB, and by patterning features in areas corresponding to the other electronic components. Thereafter, the area under the CPU and/or chipset may be more finely patterned with features than the rest of the PCB, thereby improving the pitch and the L/S specification of the PCB.

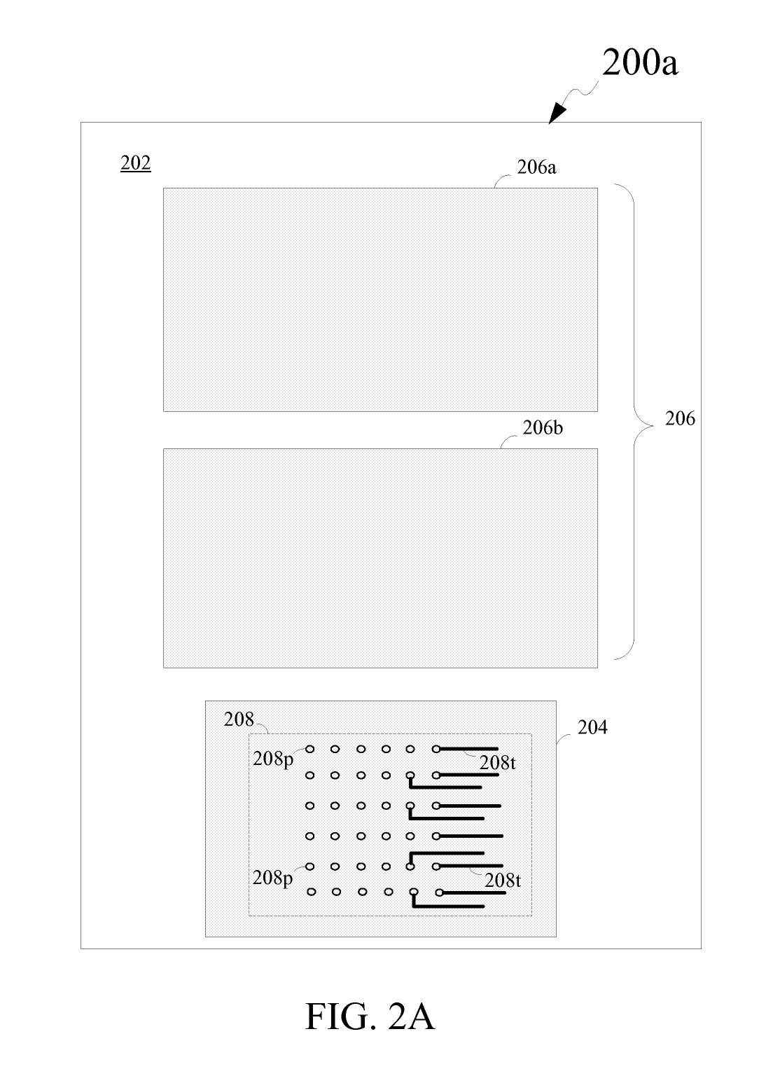

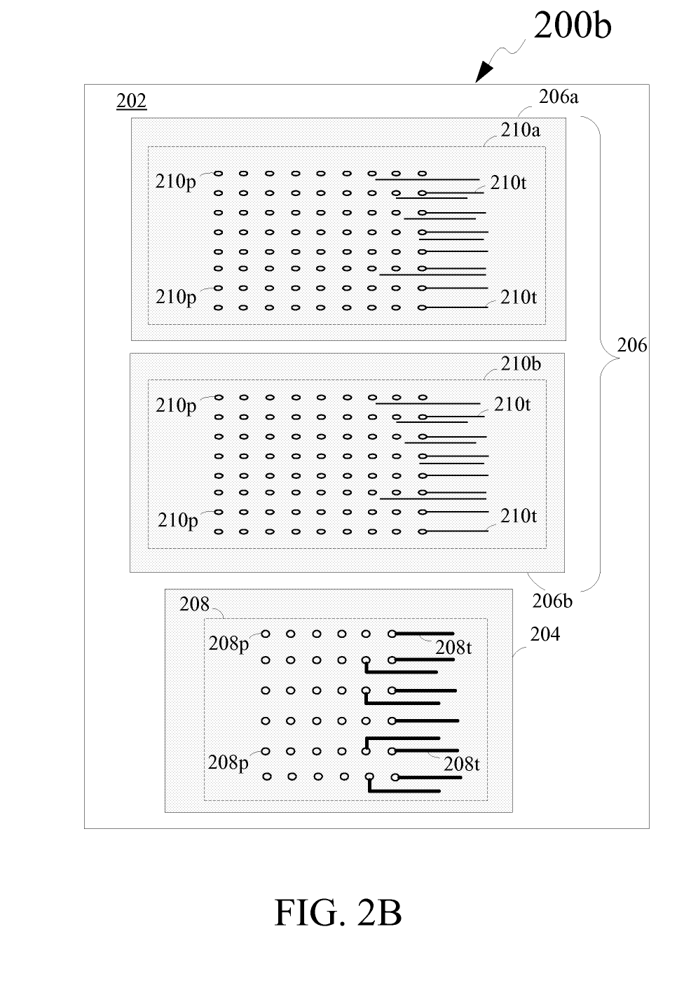

Referring to FIG. 2A, a schematic diagram of a PCB 200a, is shown, according to an exemplary embodiment of the present disclosure. The PCB 200a comprises an insulated layer substrate (not shown) and a conductive layer 202 disposed on the insulated layer substrate. The conductive layer 202 may be made of copper (Cu). As shown in FIG. 2A, the conductive layer 202 of the PCB 200a is partitioned into a first area 204 and a second area 206. In an embodiment of the present disclosure, the first area 204 is reserved to accommodate the electronic components that do not require highly dense traces and pads. Further, the second area 206 of the conductive layer 202 is intended to accommodate the electronic components such as a chipset and a CPU, which require relatively dense traces and pads. For example, the second area 206 comprises an area 206a reserved for a chipset and an area 206b reserved for a CPU.

The conductive layer 202 may be partitioned into the first area 204 and the second area 206 by applying a photoresist mask. For example, the photoresist mask is used to cover the area 206 (i.e., 206a and 206b), whereas the first area 204 is allowed to pattern features. A first etching process may be applied at the first area 204 to pattern a first set of features 208 on the conductive layer 202. The first set of features 208 comprise pads 208p and traces 208t as shown within the first area 204. In one embodiment, the first etching process is the subtractive etching process. The first set of features 208 correspond to the electronic components, which do not require highly dense pads and traces. For example, the first set of features 208 comprises pads 208p and the traces 208t, which are sparsely patterned.

Referring now to FIG. 2B, a schematic diagram of a PCB 200b, is shown, according to an exemplary embodiment of the present disclosure. As shown in FIG. 2B, a second set of features 210a and 210b corresponding to the chipset and the CPU are patterned in the areas 206a and 206b respectively by applying a second etching process. The second etching process enables to pattern highly dense traces and pads. These pads and the traces are shown as pads 210p and traces 210t within the areas 206a and 206b in the second set of features 210a and 210b. The second etching process may be selected from processes including, but not limited to, a laser ablation, a lithographic mask-based dry etching, and a lithographic mask-based wet etching. The PCB 200a in FIG. 2A is an intermediate stage PCB obtained during the preparation of the PCB 200b in FIG. 2B, which is a final PCB.

In the laser ablation process, a laser beam is used to ablate Cu from the regions where it is not desired (for example, between the pads 210p, between the traces 210t, and the like). Once laser ablation is complete, a rinse or other air clean process may be performed as needed to remove any remaining foreign materials (FM) from the conductive layer 202. The PCB 200b is then ready for mounting the electronic components. Depending on the type of the metallization material used, the dielectric mat used, the throughput requirements, and the line and space dimensions to be fabricated, the type of laser to be used in determined. This would include—but not limited to—any laser wavelength in the IR- to the UV and deep UV ranges.

In the lithographic mask-based dry etching, a lithographic mask may be used, which mask is patterned with a desired pitch and a desired L/S specification on the CPU and chipset contact regions such as the areas 206a and 206b. A dry etch is used to remove unwanted Cu, leaving the pads 210p and the traces 210t with straight sidewalls. Thereafter, the lithographic mask is removed and a rinse or other air cleaning process may be performed as needed to remove any remaining FM from the conductive layer 202. The PCB 200b is then ready for mounting the electronic components. Similarly, in the lithographic mask-based wet etching, a wet etching process may be used to remove unwanted Cu to pattern the second set of features 210a and 210b on the areas 206a and 206b respectively.

The second set of features 210a and 210b has a finer pitch of the pads 210p as compared to the pitch of the pads 208p of the first set of features 208, because the second set of features 210a and 210b are patterned using the second etching process. The processes listed herein under the second etching process are capable of providing a finer pitch and L/S specifications as compared to the first etching process used for the first set of features 208. The second set of features 210a and 210b has reduced line widths of the traces 210t and reduced space widths between the traces 210t as compared to the traces 208t of the first set of features 208. For example, in the PCB 200b, the L/S may be improved to 20/20 (μm/μm) for the traces 210t that are patterned by the second etching process as compared to 75/75 (μm/μm) for the traces 208t that are patterned by subtractive etching.

The present disclosure provides a method for preparation of a PCB as described above in conjunction with FIGS. 2A and 2B. The method comprises forming a conductive layer on an insulated layer substrate. The conductive layer may be a copper layer. The method further comprises partitioning the conductive layer into a first area and a second area by applying a photoresist mask. The first area is intended to accommodate the electronic components which require relatively less dense traces and pads. The second area is intended to accommodate the relatively dense traces and pads requiring electronic components including, but not limited to, chipsets and CPU.

Furthermore, the method for preparing the PCB comprises applying a first etching process to the conductive layer to pattern a first set of features on the first area of the conductive layer. The first etching process may be a subtractive etching process. The method also includes applying a second etching process to the conductive layer to pattern a second set of features on the second area of the conductive layer. The second etching process may be one of a laser ablation, lithographic mask-based dry etching, and a lithographic mask-based wet etching. The second set of features on the second area of the conductive layer has a finer pitch as compared to the first set of features on the first area of the conductive layer. For example, the second set of features has a reduced line width of the traces and reduced space width between the traces as compared to the first set of features.

While the foregoing description relates to PCB processes, it shall be understood that the present disclosure is not limited to PCB processes. Indeed, the processes described herein may be used to realize a selective pattern area of an HDI (high density interconnect) or LDI (low density interconnect) substrate. For example, the present disclosure may be used to achieve a high density pattern area in otherwise course patterned layer such as in the core layer of a multilayer HDI or LDI substrate.

The foregoing descriptions of specific embodiments of the present disclosure have been presented for purposes of illustration and description. They are not intended to be exhaustive or to limit the present disclosure to the precise forms disclosed, and obviously many modifications and variations are possible in light of the above teaching. The embodiments were chosen and described in order to best explain the principles of the present disclosure and its practical application, to thereby enable others skilled in the art to best utilize the present disclosure and various embodiments with various modifications as are suited to the particular use contemplated. It is understood that various omission and substitutions of equivalents are contemplated as circumstance may suggest or render expedient, but such are intended to cover the application or implementation without departing from the spirit or scope of the claims of the present disclosure.

What is claimed is:

1. A method for preparing a printed circuit board (PCB), high density interconnect (HDI) substrate or low density interconnect (LDI) substrate, the method comprising:
forming a conductive layer on an insulated layer substrate;
partitioning the conductive layer into a first area and a second area;
applying a first etching process to the conductive layer to pattern a first set of features on the first area of the conductive layer; and
applying a second etching process to the conductive layer to pattern a second set of features on the second area of the conductive layer;
wherein the second set of features on the second area of the conductive layer has a finer pitch as compared to the first set of features on the first area of the conductive layer.

2. The method of claim 1, wherein the first etching process is a subtractive etching process.

3. The method of claim 1, wherein the second etching process is one of a laser ablation, a lithographic mask-based dry etching and a lithographic mask-based wet etching.

4. The method of claim 1, wherein the second area includes at least one of a chipset region and a central processing unit region.

5. The method of claim 1, wherein the conductive layer is a copper layer.

6. An apparatus comprising:
an insulated layer substrate;
a conductive layer disposed on the insulated layer substrate, the conductive layer partitioned into a first area and a second area;
a first set of features patterned on a first area of the conductive layer; and
a second set of features patterned on a second area of the conductive layer, wherein the second set of features has a finer pitch as compared to the first set of features.

7. The apparatus of claim 6, wherein the first set of features is patterned on the first area of the conductive layer by a subtractive etching process.

8. The apparatus of claim 6, wherein the second set of features is patterned on the second area of the conductive layer by using one of a laser ablation, a lithographic mask based dry etching and a lithographic mask based wet etching.

9. The apparatus of claim 6, wherein the second area includes at least one of a chipset region and a central processing unit region.

10. The apparatus of claim 6, wherein the conductive layer is a copper layer.

11. The apparatus of claim 6, wherein said substrate is a printed circuit board (PCB) substrate.

12. The apparatus of claim 6, wherein said substrate is a high density interconnect (HDI) substrate.

13. The apparatus of claim 6, wherein said substrate is a low density interconnect (LDI) substrate.
